(19) United States
(12) Patent Application Publication
(10) Pub. No.: US 2006/0046534 A1
(43) Pub. Date: Mar. 2, 2006

(54) Video expansion card

(75) Inventor: Blair Birmingham, North York (CA)

Correspondence Address: ATI TECHNOLOGIES, INC.;C/O VEDDER PRICE KAUFMAN & KAMMHOLZ, P.C., 222 N.LASALLE STREET, CHICAGO, IL, 60601, US

(73) Assignee: ATI Technologies, inc., Markham (CA)

(21) Appl. No.: 10/932,288

(22) Filed: Sep. 1, 2004

(51) Int. Cl. H05K 1/00

(52) U.S. Cl. 439/76.1

(57) ABSTRACT

A video expansion card makes electrical contact with a mating connector via a mixed signal card edge connector formed on a first edge of the video expansion card. The mixed signal card edge connector includes a plurality of contacts to make electrical contact with the mating connector. The plurality of contacts carries, for example, any combination of two channel audio-in and two channel audio-out signals, two S-video signals, two television signals and two composite video signals, or any other suitable signals. The video expansion card may be coupled to an expansion card bracket in a housing having an aperture adapted to receive the mixed signal card edge connector. The housing may be, for example, a personal computer system chassis or cabinet, a processor-based device or any suitable device. A motherboard card edge connector is formed on a second edge of the video expansion card, and couples the video expansion card to the housing.

### FIELD OF THE INVENTION

The invention relates generally to computer card connectors and, more particularly, to a computer card connector for use in a personal computer or other devices.

### BACKGROUND OF THE INVENTION

Processor-based devices including personal computers, notebook computers, hand-held devices, set-top boxes, DVD/CD players, mobile phones and other devices are increasingly being used in multimedia applications that involve both video and audio processing. In many cases, such processing is distributed from a host central processing unit (CPU) of the processor-based device to specialized coprocessors such as video graphics coprocessors that may also perform audio processing functions. To provide additional functionality to a processor-based device and further distribute processing, the user may plug a peripheral expansion card, such as a video graphics coprocessor, into one of a number of connectors or into slots in a computer motherboard. Additionally, one or more peripheral expansion cards may transfer data to the CPU through an external input/output (I/O) bus via a connector on the motherboard. As a result, the CPU's external bus permits the processor-based device to be expanded, using a modular approach. For example, peripheral expansions of a processor-based device may include adding a video graphics processing subsystem, a sound subsystem, a communications subsystem, a compact disc (CD), a digital video disk device (DVD), a storage device or hard drive, an instrumentation interface or other special function expansions to the personal computer.

Typically, these peripheral expansion cards have a connector with pins interfacing with a motherboard card edge connector, in order to provide electrical connections between the electronic circuits on the peripheral expansion card and the computer components on the motherboard, such as the CPU. The computer components on the motherboard can access these electrical circuits on the peripheral card via the CPU's external I/O bus.

One type of external I/O bus, the peripheral component interconnect (PCI) bus, provides an interface bus to these peripheral expansion cards. The PCI bus may be processor-independent because the external PCI bus may transfer data to the local processor bus through a special bridge circuit. This provides the advantage of a bus having near-universal compatibility with other computers, since the PCI bus is compatible with a variety of personal computers: Mac OS-based computers, and RISC-type computers. Additionally, the PCI bus may support multiple bus-mastering expansion cards. The PCI bus also provides some plug-and-play capabilities.

The next generation of the PCI bus is known as PCI Express. The PCI Express configuration also uses standard mechanisms defined in the PCI plug-and-play specification. Yet another type of external I/O bus, the AGP bus is based on the PCI bus, but is designed especially for the throughput demands of 3-D graphics.

Another standard, known as the audio/modem riser (AMR) specification, defines an open industry-standard interface connector and mechanical form factor for adding a modem and audio/modem riser card to ATX, micro ATX and NLX circuit board form factors. However, the AMR specification does not define an aftermarket I/O standard expansion slot. Instead, the AMR specification defines only a system manufacturer, motherboard-only riser interface that is intended to be fully configured prior to the initial shipment of the system. As a result, the PCI bus standard typically serves as the aftermarket I/O interface. The Intel Corporation publication Audio/Modem Riser Specification (1998) provides additional details on the AMR specification.

In order to provide all of the audio and video signals to such video graphics expansion cards for processing, a wide variety of different signal formats (e.g., both analog and digital) may be supported. As the number of signals provided to such video graphics expansion cards increases, the number of required connector contacts also increases. In addition, some connectors are quite complex and large, such as the digital video interface (DVI) connector developed by Intel Corporation for driving digital displays. The dimensions of the DVI connector with respect to the mounting surface are almost twice those of the standard video graphics adapter (VGA) connectors commonly used for driving conventional displays today.

In order to transmit the signals to the video graphics expansion card, the connectors are typically placed along the back of the video graphics expansion card as it is mounted in the personal computer chassis. The video graphics expansion card may interface with a motherboard on the personal computer chassis via the accelerated graphics port (AGP) bus. An expansion card bracket that is used for mounting the expansion card in the personal computer chassis typically includes a number of apertures that allow access to the various connectors on the video graphics expansion card.

FIG. 1 illustrates a view of a prior art bracket 2 that is shown to include a number of apertures corresponding to various connectors that are commonly used for relaying audio and video signals. The rightmost-aperture is designed for a DVI connector 4 commonly used for driving a display device, whereas the other apertures may be used to carry mixed signals, such as analog and digital audio information via an S-video connector 6 and RF signals via a coaxial connector 8. Unfortunately, the connectors illustrated in FIG. 1 may not be able to support all of the number and type of signals and other functional capabilities that may be required by some video graphics expansion cards being developed today and in the future in a cost-efficient manner.

According to another known method, a pre-assembled connector is attached to a video graphics expansion card and has an array of pins to provide a mixture of signals, including analog and digital signals. However, attaching this pre-assembled connector to the video graphics expansion card increases both material costs and manufacturing costs. Further, this connector supports only a limited number of connections, and therefore may not be able to support, in a cost-efficient manner, the number of signals and other functional capabilities that may be provided by some video graphics expansion cards.

### BRIEF DESCRIPTION OF THE DRAWINGS

The present invention is illustrated by way of example and not limitation in the accompanying figures, in which like reference numerals indicate similar elements and in which:

FIG. 1 illustrates a frontal view of an ATX bracket and the apertures associated with prior art connectors;

FIG. 2 illustrates a frontal view of an expansion card bracket that includes apertures for providing access to a mixed signal card edge connector in accordance with one exemplary embodiment of the present invention;

FIG. 3 illustrates a frontal view of the expansion card bracket that includes apertures for providing access to the mixed signal card edge connector and a digital signal connector in accordance with one exemplary embodiment of the present invention;

FIG. 4 illustrates a video expansion card assembly that includes the mixed signal card edge connector of FIG. 2 in accordance with one exemplary embodiment of the present invention;

FIG. 5 illustrates a computer system that includes the mixed signal card edge connector in accordance with another exemplary embodiment of the present invention;

FIG. 6 illustrates a motherboard that includes the mixed signal card edge connector in accordance with yet another exemplary embodiment of the invention; and

FIG. 7 illustrates an adapter connector cable according to one embodiment of the invention.

### DETAILED DESCRIPTION

A video expansion card makes electrical contact with a mating connector via a mixed signal card edge connector formed on a first edge of the video expansion card. The mixed signal card edge connector includes a plurality of contacts to make electrical contact with the mating connector. The plurality of contacts carries, for example, any combination of two channel audio-in and two channel audio-out signals, two S-video signals, two television signals and/or two composite video signals, or any other suitable signals. The video expansion card may be coupled to an expansion card bracket in a housing having an aperture adapted to receive the mixed signal card edge connector. The housing may be, for example, a personal computer system chassis, cabinet, a processor-based device or any suitable device. A motherboard card edge connector is formed on a second edge of the video expansion card and couples the video expansion card to the housing.

Among other advantages, the mixed signal card edge connector supports a large number of mixed signals that may include analog signals, digital signals and high-frequency analog and radio frequency signals. Additionally, the mixed signal card edge connector does not require the installation of a pre-assembled connector on the video expansion card, and therefore reduces both the material costs and the costs of manufacturing the video expansion card. Further, according to one embodiment, the mixed signal card edge connector is compatible with the PCI bus type interface such as the PCI, PCI express bus, or any suitable bus interface, and therefore, the mixed signal card edge connector is economical to make and use. Further yet, the mixed signal card edge connector is compact in size, such that it is easily accommodated within the space available on an expansion card bracket and may leave room to accommodate additional connectors for other signals.

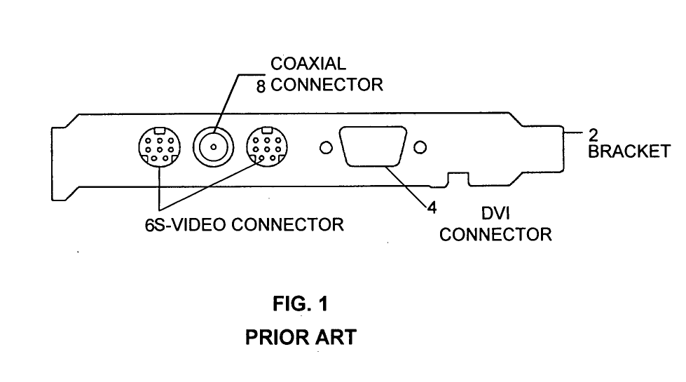

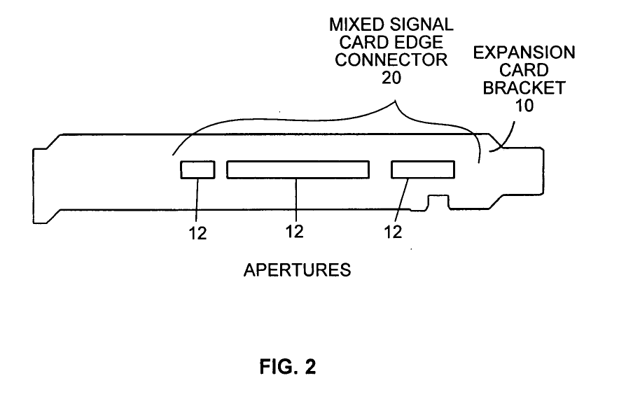

FIG. 2 illustrates a frontal view of an expansion card bracket 10 that includes apertures 12 for providing access to a mixed signal card edge connector 20, in accordance with one exemplary embodiment of the present invention. The expansion card bracket 10 may be associated with, for example, an ATX form factor for expansion cards, and therefore may comply with the mechanical and electrical specifications for building a personal computer motherboard and a chassis to house the motherboard and expansion card. The expansion card bracket 10 is shown to include three apertures 12 within which the mixed signal card edge connector 20 may be positioned; however, the expansion card bracket 10 may include fewer apertures, such as one or two apertures, or alternatively more apertures to suit the mixed signal card edge connector 20 and any other connectors. For example, the expansion card bracket 10 may include apertures to allow the installation of an S-video connector 6 and a coaxial connector 8, as previously described with respect to FIG. 1.

According to one embodiment, the mixed signal card edge connector 20 extends through the expansion card bracket 10 via the apertures 12 to expose a plurality of contacts on the mixed signal card edge connector 20. Although the mixed signal card edge connector 20 shown is similar in appearance to a PCI type bus or an AGP bus, any proprietary, non-proprietary or industry standard connector and bus may be used. For example, the mixed signal card edge connector 20 may be compatible with a PCI express bus, a USB bus, an I²C serial bus, an IEEE 1394 bus, or any suitable type bus interface standard.

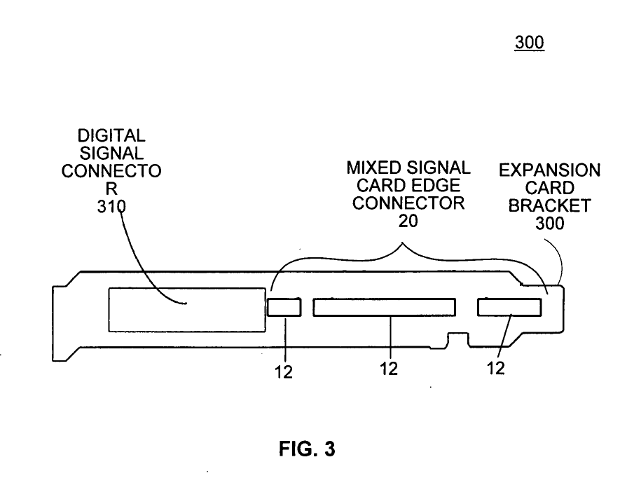

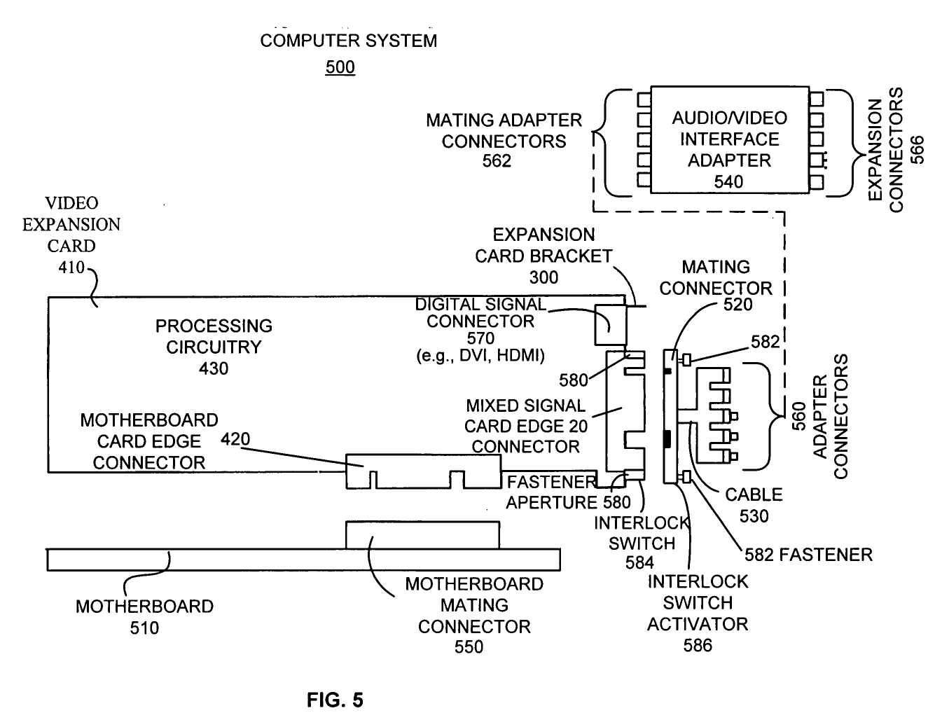

FIG. 3 illustrates a frontal view of an expansion card bracket 300 that includes apertures 12 for providing access to the mixed signal card edge connector 20 and a digital signal connector 310, in accordance with another exemplary embodiment of the present invention. The digital signal connector 310 and the mixed signal card edge connector 20 are integrated onto the expansion card bracket 300 to permit placement of the expansion card bracket 300 within the personal computer chassis. The mixed signal card edge connector 20 may include a plurality of contacts, as is commonly known in a PCI bus. For example, the plurality of contacts may further provide contacts for any combination of: a digital audio signal, a radio frequency (RF) signal, a DVI signal, a high-definition multimedia interface (HDMI) signal, and/or at least one ground signal. According to one embodiment, the mixed signal card edge connector 20 and the corresponding mating connector 520 (shown in FIG. 5), when interconnected, provide a suitable shield for reducing the emissions of electromagnetic signals.

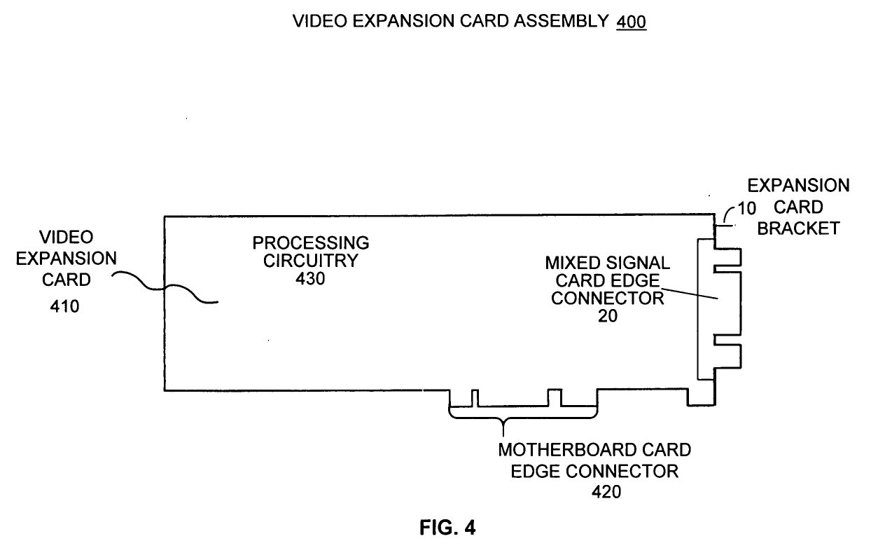

FIG. 4 illustrates a video expansion card assembly 400 that includes the mixed signal card edge connector 20 in accordance with one exemplary embodiment of the present invention. The video expansion card assembly 400 also includes a video expansion card 410, a motherboard card edge connector 420 and processing circuitry 430.

The video expansion card 410 includes the mixed signal card edge connector 20 formed on a first edge of the video expansion card 410. The mixed signal card edge connector 20 includes a plurality of contacts, such that the plurality of contacts carry any suitable combination of the following signals: two (2) channel audio-in and two (2) channel audio-out signals, two (2) S-video signals, two (2) television signals and/or two (2) composite video signals. The plurality of contacts may carry additional or fewer suitable signals. As previously stated, the expansion card bracket 10 includes apertures 12 (shown in FIG. 3) adapted to receive the mixed signal card edge connector 20.

The motherboard card edge connector 420 is formed on a second edge of the video expansion card 410. The motherboard card edge connector 420 couples the video expansion card 410 to the housing, as is commonly known.

The video expansion card 410 may be a video graphics card, a PC-TV tuner, a video editor, a video server or any other suitable device for providing video functionality. For example, the video expansion card 410 may be an “All In Wonder” video graphics card manufactured by ATI, Incorporated. The PC-TV tuner may receive a broadcast television signal, an RF signal, a television base-band signal, or a digital television signal from a digital television receiver, or cable box. Accordingly, the video expansion card 410 may include suitable processing circuitry 430 that may also include, for example, an analog or digital tuner to receive radio or television signals. According to one embodiment, the video expansion card 410 includes a TV tuner suitable for demodulating and displaying television signals on a computer system display. For example, the video expansion card 410 may be a stand-alone dedicated TV tuner and, therefore, does not require a graphic processor unit. Additionally, the PC-TV tuner may receive a digital signal from the Internet. In response to receiving the television signals, the PC-TV tuner may then function to provide a television picture on a computer display. Additionally, the video expansion card 410 may further include a video editor suitable for editing images and audio, as is known in the art. According to one embodiment, the video expansion card 410 includes at least one coaxial cable connector to provide, for example, any combination of a frequency-modulated (FM) radio signal, an amplitude-modulated (AM) radio signal, a satellite television signal, a television signal and a high-definition television (HDTV) signal.

FIG. 5 illustrates a computer system 500 that includes the mixed signal card edge connector 20 in accordance with another exemplary embodiment of the present invention. The computer system 500 includes a motherboard 510, the video expansion card 410, a mating connector 520, a cable 530, and an optional audio/video interface adapter 540, a motherboard mating connector 550 and adapter connectors 560. The motherboard mating connector 550 makes electrical contact with the motherboard card edge connector 420, as is known in the art.

The mating connector 520 includes a plurality of contacts to make electrical contact with the mixed signal card edge connector 20, such that the plurality of contacts carries any suitable combination of the following: two (2) channel audio-in and two (2) channel audio-out signals, two (2) S-video signals, two (2) television signals and/or two (2) composite video signals. As previously stated, the plurality of contacts may carry additional or fewer suitable signals.

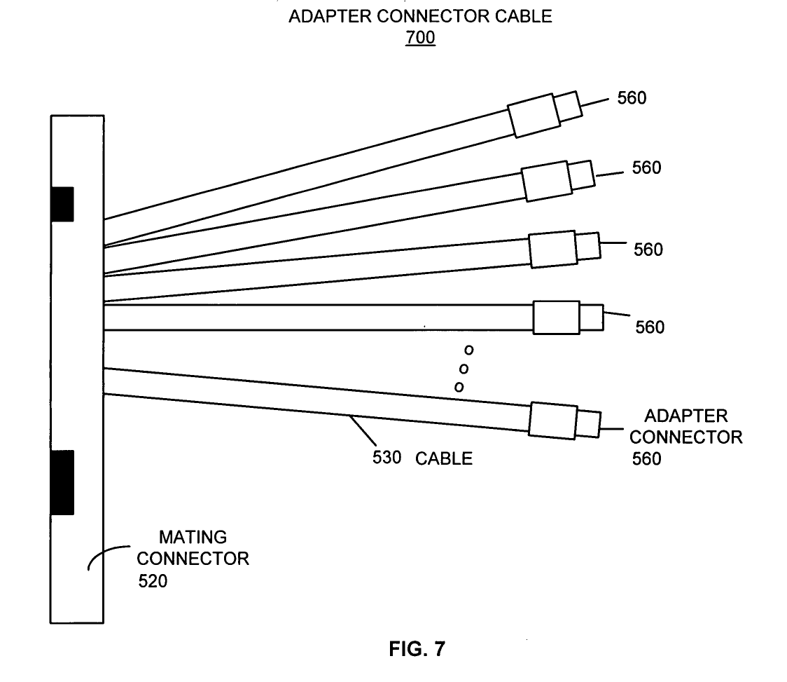

As is also shown in FIG. 7, the cable 530 includes at one end the mating connector 520 and at the other end, adapter connectors 560. The mating connector 520 makes electrical contact with the mixed signal card edge connector 20. The adapter connectors 560 make electrical contact with adapter mating connectors 562 on the optional audio/video interface adapter 540. The audio/video interface adapter 540 may be an audio/video receiver that receives audio, video and RF signals (i.e., digital or analog) from the video expansion card 410 for processing and distributing the audio, and RF video signals to an audio/video system, such as a stereo system, a surround sound system, a television system, a video server, or any suitable device. According to an alternative embodiment, the audio/video interface adapter 540 includes switching devices in order to route the appropriate audio, video and RF signals from the video expansion card 410 to an appropriate device such as an audio/video system, as is known in the art. According to yet another embodiment, audio/video interface adapter 540 includes expansion connectors 566 providing connectors in addition to those available on adapter connectors 560.

The adapter connectors 560 and the corresponding mating adapter connectors 562 may include, for example, a coaxial connector, an S-video connector, a composite video connector, an RCA audio connector, a DVI connector, an HDMI connector, a stereo miniplug connector and a USB connector. Although five (5) connectors are shown as adapter connectors 560 in FIG. 5, more or fewer connectors may be used. Further, any connector may be used for adapter connectors 560 and adapter mating connectors 562 suitable for providing an interconnection between the mixed signal card edge connector 20 and the audio/video interface adapter 540.

According to the embodiment shown in FIG. 5, the video expansion card 410 includes a digital signal connector 570. The digital signal connector 570 may be, for example, a DVI connector and/or an HDMI connector. According to one embodiment, the mixed signal card edge connector 20 receives signals in the Sony Panasonic digital interface format (SPDIF), as is known in the art.

According to one embodiment, the expansion card bracket 300 includes at least one fastener aperture 580 coupled to at least one fastener 582, included in the mating connector 520. For example, the fastener 582 may be used to couple the mating connector 520 with the mixed signal card edge connector 20 in order to prevent or reduce the separation of the mating connector 520 from the mixed signal card edge connector 20. The fastener 582 may therefore engage a corresponding mating fastener in the fastener aperture 580 in order to provide a suitable mechanical connection. According to one embodiment, the fastener 582 is a bolt, screw or spring clip, and the fastener aperture 580 is a corresponding mating nut or clip tab. Alternatively, the fastener 582 may be a push-in connector, including a suitable spring mechanism to activate a latch in order to engage the fastener aperture 580.

According to one embodiment, an interlock switch 584 is coupled to the expansion card bracket 300. When the interlock switch activator 586, such as a tab, prong, magnet, light or any suitable device, engages the interlock switch 584, the interlock switch 584 disables at least one of the contacts in the mixed signal card edge connector 20. Disabling at least one of the contacts in the mixed signal card edge connector 20 may protect the contacts and the signals on the contacts to prevent the contacts from short circuiting. As a result, disabling at least one contact on the mixed signal card edge connector 20 may protect the video expansion card 410 from being damaged during, for example, installation, shipping, repair, or even while the video expansion card 410 is operating. The interlock switch 584 may be a mechanical switch, a magnetic switch, a photo detector or any other suitable device for detecting the presence of the interlock switch activator 586. Further, the interlock switch 584 may include electronic circuitry, such as discrete transistor circuits suitable for enabling and disabling electrical signals to the contacts of the mating connector 520.

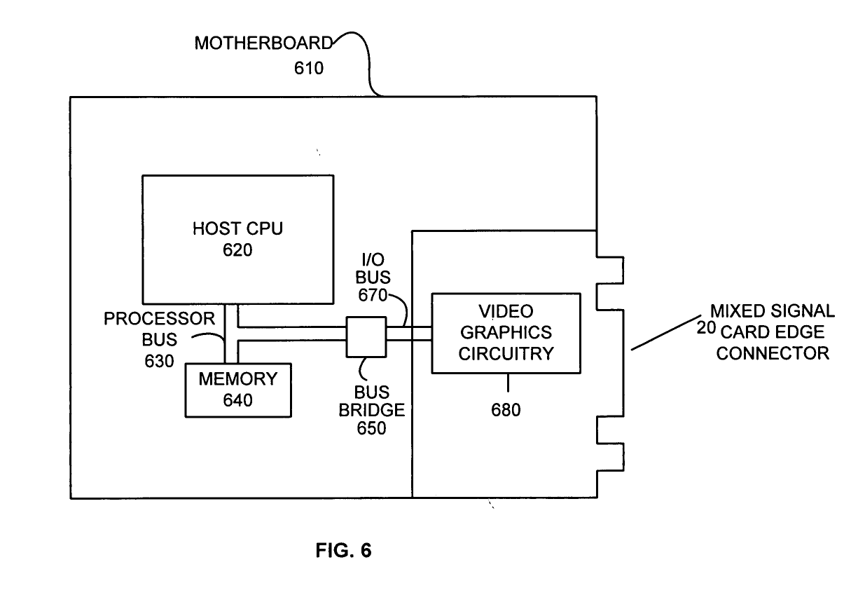

FIG. 6 illustrates a motherboard 610 that includes the mixed signal card edge connector 20 in accordance with another exemplary embodiment of the invention. The motherboard 610 includes a host CPU 620, a processor bus 630, memory 640, a bus bridge 650, an I/O bus 670 and video graphics circuitry 680, as is commonly known in the art. According to an alternative embodiment, the motherboard 610 may include a digital signal processor or a co-processor rather than the host CPU 620. The motherboard 610 may include other suitable support circuitry.

According to one embodiment, the motherboard 610 includes a substrate, such as a circuit board, for interconnection with another substrate, such as a daughter board. A substrate may include for example, a circuit board with suitable circuitry, an integrated circuit with suitable circuitry or any suitable device to support circuitry. In the example shown in FIG. 5, the motherboard 510 interconnects with the video expansion card 410 although the motherboard 510 may interconnect with the video expansion card 410 or any other suitable expansion card in any suitable manner.

According to an alternative embodiment, the motherboard 610 does not interconnect with another substrate such as a daughter board. For example, the motherboard 610 is a circuit substrate that includes the host CPU 620, the processor bus 630, memory 640, the bus bridge 650, the I/O bus 670 and video graphics circuitry 680 and suitable related circuitry. As such, in FIG. 6, the motherboard 610 includes the video graphics processor 680 and suitable related circuitry, and therefore, does not require a separate video expansion card 410. According to one embodiment, the circuit substrate may be used in a device that is typically not expandable, such as a set top box or DVD/CD player or other suitable device. According to this exemplary embodiment, the mixed signal card edge connector 20 is formed on an edge of the motherboard 610 and includes the plurality of contacts operative to make electrical contacts with the mating connector 520.

Among other advantages, the mixed signal card edge connector 20 supports a large number of mixed signals that may include analog signals, digital signals and high-frequency analog and radio frequency signals. Additionally, the mixed signal card edge connector 20 does not require the installation of a pre-assembled connector on the video expansion card 410, and therefore reduces both the material costs and the cost of manufacturing the video expansion card. Further, according to one embodiment, the mixed signal card edge connector 20 is compatible with the PCI type bus interface such as the PCI, PCI express bus, or any suitable bus interface, and therefore, it is economical to make and use. Further yet, the mixed signal card edge connector 20 is compact in size, such that it is easily accommodated within the space available on a bracket and may include additional connectors for other signals.

It is understood that the implementation of other variations and modifications of the present invention and its various aspects will be apparent to those of ordinary skill in the art, and the invention is not limited by the specific embodiments described. It is, therefore, contemplated to cover by the present invention any and all modifications, variations, or equivalence that fall within the spirit and scope of the basic underlined principles disclosed and claimed herein.

1. A video expansion card, comprising:
a mixed signal card edge connector formed on a first edge of the video expansion card, including a plurality of contacts operative to make electrical contact with a mating connector, such that the plurality of contacts carries at least: two (2) channel audio-in and two (2) channel audio-out signals, two (2) S-video signals, two (2) television signals and two (2) composite video signals; and
a motherboard card edge connector formed on a second edge of the video expansion card and operative to couple the video expansion card to a housing.

2. The video expansion card of claim 1, wherein the mixed signal card edge connector is compatible with at least one of: a peripheral component interconnect (PCI) bus, a PCI Express bus, an accelerated graphics port (AGP) bus, a universal serial bus (USB), an I²C serial bus and an IEEE 1394 bus.

3. The video expansion card of claim 1, wherein the plurality of contacts further provides electrical contacts for at least one of: a digital audio signal, a radio frequency (RF) signal, a digital video interface (DVI) signal, a high-definition multimedia interface (HDMI) signal and at least one ground signal.

4. The video expansion card of claim 1, wherein the video expansion card is coupleable to a cable including a first end and a second end, such that the first end is operatively coupleable to the mating connector and the second end is coupleable to at least one adapter connector.

5. The video expansion card of claim 4, wherein the at least one adapter connector includes at least one of: a coaxial connector, an S-video connector, a composite video connector, an RCA audio connector, a DVI connector, an HDMI connector, a stereo miniplug connector and a USB connector.

6. The video expansion card of claim 1, further including at least one coaxial cable connector operatively coupled to the video expansion card wherein the at least one coaxial cable connector provides at least one of: a frequency-modulated radio signal, an amplitude-modulated radio signal, a satellite television signal, a television signal and a high-definition television (HDTV) signal.

7. The video expansion card of claim 1, wherein the video expansion card is operatively coupleable to an expansion card bracket having at least one aperture adapted to receive the mixed signal card edge connector and at least one other aperture adapted to receive at least one of: a DVI connector and an HDMI connector.

8. The video expansion card of claim 1, wherein the video expansion card is operatively coupleable to an expansion card bracket and wherein the expansion card bracket further includes at least one fastener aperture, wherein the at least one fastener aperture is adapted to couple to at least one fastener included in the mating connector.

9. The video expansion card of claim 1, including:
an interlock switch coupled to the mixed signal card edge connector operative to disable at least one of the plurality of contacts; and
an interlock switch actuator attached to the mating connector operative to engage the interlock switch when the mating connector engages the mixed signal connector to disable at least one of the plurality of contacts.

10. A computer system comprising:
a motherboard including a motherboard mating connector;
a video expansion card including:
a mixed signal card edge connector formed on a first edge of the video expansion card, including a plurality of contacts operative to make electrical contact with a mating connector, such that the plurality of contacts carries at least: two (2) channel audio-in and two (2) channel audio-out signals, two (2) S-video signals, two (2) television signals and two (2) composite video signals;
a motherboard card edge connector formed on a second edge of the video expansion card and operative to couple the video expansion card to the motherboard mating connector; and
an expansion card bracket operatively coupled to the video expansion card, wherein the expansion card bracket has at least one aperture adapted to receive the mixed signal card edge connector.

11. The computer system of claim 10, wherein the mixed signal card edge connector is compatible with at least one of: a PCI bus, a PCI Express bus, an AGP bus, an I²C serial bus, a USB and an IEEE 1394 bus.

12. The computer system of claim 10, wherein the plurality of contacts further provides electrical contact for at least one of: a digital audio signal, a radio frequency signal, a DVI signal, an HDMI signal and at least one ground signal.

13. The computer system of claim 10, further including:
a cable including a first end and a second end such that the first end is operatively coupled to the mating connector; and
an audio/video interface adapter operatively coupled to the second end.

14. The computer system of claim 13, wherein the second end includes at least one of: a coaxial connector, an S-video connector, a composite video connector, an RCA audio connector, a DVI connector, an HDMI connector, a stereo miniplug and a USB connector.

15. The computer system of claim 10, further including at least one coaxial cable connector operatively coupled to the video graphics expansion card wherein the at least one coaxial cable connector provides at least one of: a frequency-modulated radio signal, an amplitude-modulated radio signal, a satellite television signal, a radio frequency television signal and a high-definition television signal.

16. The computer system of claim 10, wherein the expansion card bracket has at least one other aperture adapted to receive at least one of: a DVI connector and an HDMI connector.

17. The computer system of claim 10, wherein the expansion card bracket further includes at least one fastener aperture, wherein the at least one fastener aperture is adapted to couple to at least one fastener included in the mating connector.

18. The computer system of claim 10, including:
an interlock switch coupled to the mixed signal card edge connector operative to disable at least one of the plurality of contacts; and
an interlock switch actuator attached to the mating connector operative to engage the interlock switch when the mating connector engages the mixed signal connector to disable at least one of the plurality of contacts.

19. A motherboard comprising:
a processor;
memory operatively coupled to the processor via a processor bus;
a bus bridge operatively coupled to the host processor and the memory via the processor bus;
a video graphics processor operatively coupled to the bus bridge via an I/O bus;
a mixed signal card edge connector formed on an edge of the motherboard, including a plurality of contacts operative to make electrical contact with a mating connector, such that the plurality of contacts carry at least: two (2) channel audio-in and two (2) channel audio-out signals, two (2) S-video signals, two (2) television signals and two (2) composite video signals.

20. The motherboard of claim 19, wherein the mixed signal card edge connector is compatible with at least one of: a PCI bus, a PCI Express bus, an AGP bus, an I²C serial bus, a USB and an IEEE 1394 bus.

21. A circuit substrate comprising:
a processor;
memory operatively coupled to the processor via a processor bus;
a bus bridge operatively coupled to the host processor and the memory via the processor bus;
a video graphics processor operatively coupled to the bus bridge via an I/O bus;
a mixed signal card edge connector formed on an edge of the motherboard, including a plurality of contacts operative to make electrical contact with a mating connector, such that the plurality of contacts carries at least: two (2) channel audio-in and two (2) channel audio-out signals, two (2) S-video signals, two (2) television signals and two (2) composite video signals.

22. The circuit substrate of claim 21, wherein the mixed signal card edge connector is compatible with at least one of: a PCI bus, a PCI Express bus, an AGP bus, an I²C serial bus, a USB and an IEEE 1394 bus.
